(19) United States
(12) Patent Application Publication
(10) Pub. No.: US 2024/0272552 A1
(43) Pub. Date: Aug. 15, 2024

(54) PREFERENTIAL INFILTRATION IN LITHOGRAPHIC PROCESS FLOW FOR EUV CAR RESIST

(71) Applicant: Applied Materials, Inc., Santa Clara, CA (US)

(72) Inventors: GABRIELA ALVA, Santa Clara, CA (US); ZHENXING HAN, Sunnyvale, CA (US); MADHUR SACHAN, Belmont, CA (US); CHI-I LANG, Cupertino, CA (US); LIN ZHOU, San Jose, CA (US); LEQUN LIU, San Jose, CA (US); NASRIN KAZEM, Santa Clara, CA (US)

(21) Appl. No.: 18/407,776

(22) Filed: Jan. 9, 2024

Related U.S. Application Data
(60) Provisional application No. 63/444,852, filed on Feb. 10, 2023.

(51) Int. Cl. G03F 7/039; G03F 7/00; G03F 7/11; G03F 7/20

(52) U.S. Cl. CPC G03F 7/0392; G03F 7/11; G03F 7/2026; G03F 7/70033

(57) ABSTRACT

Embodiments disclosed herein include a method of patterning a substrate. In an embodiment, the method comprises, disposing a photoresist layer over a substrate, and exposing the photoresist layer to form an exposed region and an unexposed region in the photoresist layer. In an embodiment, the method further comprises treating either the exposed region or the unexposed region with a sequential infiltration synthesis (SIS) process to form a treated region, and developing the photoresist layer to remove portions of the photoresist layer other than the treated region.

### CROSS-REFERENCE TO RELATED APPLICATIONS

This application claims the benefit of U.S. Provisional Application No. 63/444,852, filed on Feb. 10, 2023, the entire contents of which are hereby incorporated by reference herein.

### BACKGROUND

### 1) Field

Embodiments of the present disclosure pertain to the field of semiconductor processing and, in particular, to sequential infiltration synthesis (SIS) for extreme ultraviolet (EUV) resist developing.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). Now the photoresist is developed and the pattern can be transferred to the underlying thin film or substrate by etching. After the pattern is transferred, the residual photoresist is removed and repeating this process many times can give 2D and 3D structures to be used in microelectronic devices.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of patterning a substrate. In an embodiment, the method comprises, disposing a photoresist layer over a substrate, and exposing the photoresist layer to form an exposed region and an unexposed region in the photoresist layer. In an embodiment, the method further comprises treating either the exposed region or the unexposed region with a sequential infiltration synthesis (SIS) process to form a treated region, and developing the photoresist layer to remove either portions of the treated regions or portions of the photoresist layer other than the treated region.

Embodiments disclosed herein may also include a method of processing a substrate with a photoresist layer. In an embodiment, the method comprises exposing the photoresist layer with extreme ultraviolet (EUV) radiation to form an exposed region and an unexposed region, where the exposed region is adjacent to and contacting the exposed region. In an embodiment, the method further comprises treating the photoresist layer with a sequential infiltration synthesis (SIS) process to form a treated region, where the treated region is either in the exposed region or the unexposed region, and developing the photoresist layer so that the treated region remains. In an embodiment, the method further comprises etching the substrate using the treated region as a mask.

Embodiments disclosed herein may also comprise a method of processing a substrate with a photoresist layer. In an embodiment, the method comprises exposing the photoresist layer to extreme ultraviolet (EUV) radiation to form an exposed region and an unexposed region, and selectively depositing a capping layer over either the exposed region or the unexposed region. In an embodiment, the method further comprises developing the photoresist layer so that the capping layer and the underlying one of the exposed region or the unexposed region remain, and etching the substrate using the capping layer and the underlying one of the exposed region or the unexposed region as a mask.

### BRIEF DESCRIPTION OF THE DRAWINGS

FIG. 1A is a cross-sectional illustration of a substrate with a photoresist layer, in accordance with an embodiment.

FIG. 1B is a cross-sectional illustration of the substrate during exposure of the photoresist layer, in accordance with an embodiment.

FIG. 1C is a cross-sectional illustration of the substrate with a developed photoresist, in accordance with an embodiment.

FIG. 1D is a cross-sectional illustration of the substrate with a treated photoresist, in accordance with an embodiment.

FIG. 1E is a cross-sectional illustration of the substrate after an etching process, in accordance with an embodiment.

FIG. 2A is a cross-sectional illustration of a substrate with a photoresist layer, in accordance with an embodiment.

FIG. 2B is a cross-sectional illustration of the substrate during exposure of the photoresist layer, in accordance with an embodiment.

FIG. 2C is a cross-sectional illustration of the substrate with the exposed regions of the photoresist layer after being treated, in accordance with an embodiment.

FIG. 2D is a cross-sectional illustration of the substrate with the photoresist layer developed, in accordance with an embodiment.

FIG. 2E is a cross-sectional illustration of the substrate after etching, in accordance with an embodiment.

FIG. 3A is a cross-sectional illustration of a substrate with a photoresist layer during exposure, in accordance with an embodiment.

FIG. 3B is a cross-sectional illustration of the substrate after the photoresist layer is treated, in accordance with an embodiment.

FIG. 3C is a cross-sectional illustration of the substrate after the photoresist layer is developed, in accordance with an embodiment.

FIG. 3D is a cross-sectional illustration of the substrate after the substrate is etched, in accordance with an embodiment.

FIG. 4A is a cross-sectional illustration of a substrate with an exposed photoresist layer that includes a capping layer over exposed regions, in accordance with an embodiment.

FIG. 4B is a cross-sectional illustration of the substrate after the photoresist layer is developed, in accordance with an embodiment.

FIG. 4C is a cross-sectional illustration of the substrate after the substrate is etched, in accordance with an embodiment.

FIG. 5A is a cross-sectional illustration of a substrate with an exposed photoresist layer with a capping layer over the unexposed regions, in accordance with an embodiment.

FIG. 5B is a cross-sectional illustration of the substrate after the photoresist layer is developed, in accordance with an embodiment.

FIG. 5C is a cross-sectional illustration of the substrate after the substrate is etched, in accordance with an embodiment.

FIG. 6 is a plan view illustration of a cluster tool that may be used to process a substrate with an exposed photoresist layer, in accordance with an embodiment.

FIG. 7 illustrates a block diagram of an exemplary computer system, in accordance with an embodiment of the present disclosure.

### DETAILED DESCRIPTION

Sequential infiltration synthesis (SIS) for extreme ultraviolet (EUV) resist developing are described herein. In the following description, numerous specific details are set forth, such as thermal vapor phase processes and material regimes for developing photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Chemically amplified resists (CARs) include chemistry that is sensitive to the EUV radiation. The chemical amplification concept uses a photochemically-generated acid as a catalyst. The catalyst induces a cascade of chemical transformations in the resist film, providing a gain mechanism to fully convert exposed regions of the photoresist. The converted regions of the CAR are then etch selective to the unexposed regions. As such, a developing process can be used to remove the exposed regions leaving the unexposed regions intact, or to remove the unexposed regions leaving the exposed regions intact.

In other instances, organic-inorganic hybrid materials (e.g., metal-oxo materials systems) have been proposed as a material system for EUV lithography due to the increased sensitivity to EUV radiation. Such material systems typically comprise a metal (e.g., Sn, Hf, Zr, etc.), oxygen, and carbon. Metal-oxo based organic-inorganic hybrid materials have also been shown to provide lower LER, LWR, and higher resolution, which are required characteristics for forming narrow features.

In a metal-oxo photoresist system, exposure to EUV radiation results in crosslinking and the removal of carbon. The difference in the carbon percentage between the exposed regions and the unexposed regions is used as the solubility switch during developing. Particularly, the unexposed regions with the higher carbon content are preferentially etched by the developer solution in a negative tone develop. Though, it is to be appreciated that a positive tone develop may also be used in some embodiments.

That is to say, there are several approaches for providing high sensitivity EUV photoresists. However, after developing the photoresist, the resulting pattern may not have sufficient etch selectivity to the underlying substrate in order to provide patterned features with a desired accuracy, resolution, critical dimension (CD), line edge roughness (LER), line width roughness (LWR), or the like. Accordingly, a modification process called sequential infiltration synthesis (SIS) can be carried out in order to modify the photoresist. The modification increases the robustness of the photoresist and provides further protection from the etching chemistry. In some embodiments, the SIS process may include introducing a metal containing precursor to form a metal oxide material (e.g., alumina) in the photoresist layer. Embodiments may also use a nitrogen containing gas to form a metal nitride material in the photoresist layer. Though, non-metal SIS processes may also be used in some embodiments. For example, SiCl₄ can be provided as a precursor and nitrided with an NH₃ gas.

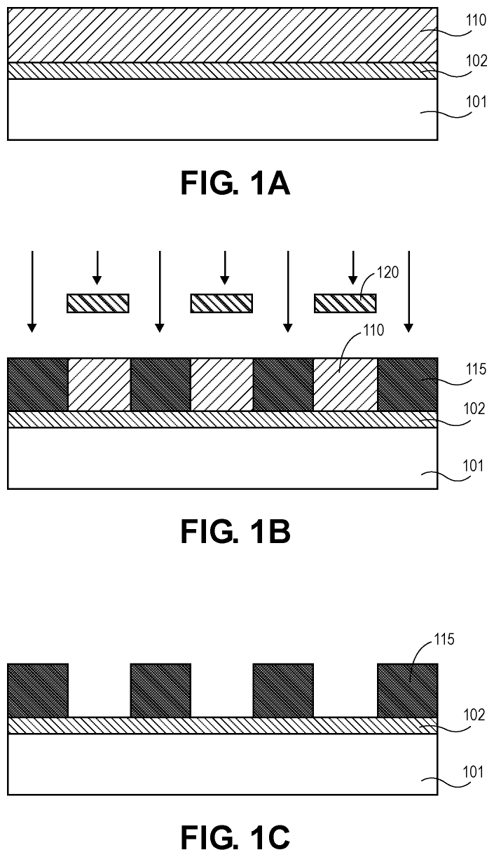

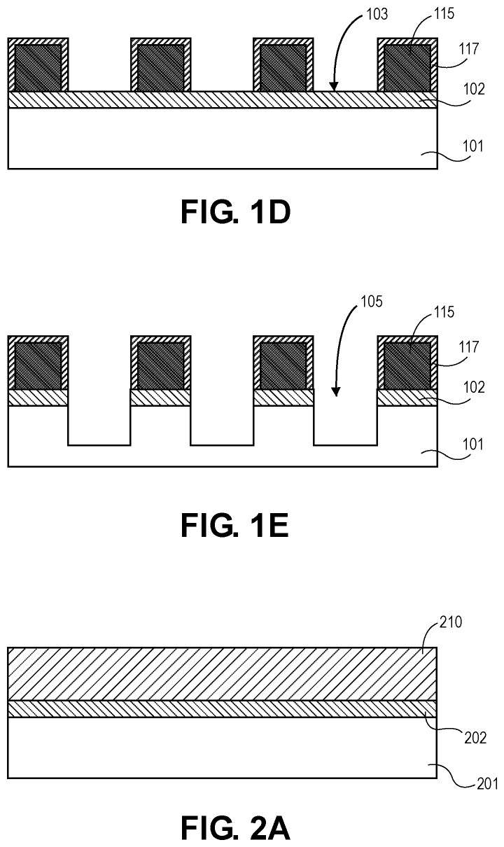

Referring now to FIGS. 1A-1E, a series of cross-sectional illustrations depicting an EUV photolithography patterning process that includes an SIS treatment is shown. The SIS treatment shown in FIGS. 1A-1E may be considered a conventional treatment. A conventional treatment describes a process where the SIS process is implemented after the photoresist layer is developed.

Referring now to FIG. 1A, a cross-sectional illustration of a substrate 101 is shown. The substrate 101 may be a semiconductor substrate, such as silicon. The substrate 101 may be other materials as well, such as an oxide, a nitride, a metal, or any other material useful in semiconductor fabrication operations. The substrate 101 may have a form factor that is standard for semiconductor processing, such as a wafer (e.g., a 200 mm wafer, a 300 mm wafer, a 450 mm wafer, etc.).

In some instances, the substrate 101 may be covered by an underlayer 102. The underlayer 102 may be one or more of an antireflective coating (ARC), a hardmask layer, or any other layer for enhancing patterning. A photoresist layer 110 may be provided over the underlayer 102. The photoresist layer 110 may be an CAR or a metal-oxo photoresist system. The photoresist layer 110 may be tuned for absorbing and reacting with EUV radiation. Though, DUV radiation may also be used in some instances.

Referring now to FIG. 1B, a cross-sectional illustration of the substrate 101 during a lithography exposure process is shown. The lithography exposure process may include the use of EUV or DUV radiation (indicated by the arrows) that passes through a mask 120, reticle, or the like. The openings in the mask 120 result in exposed regions 115 being formed in the photoresist layer 110. The exposed regions 115 may have an etch selectivity to the unexposed regions of the photoresist layer 110. The exposure process may be followed by a post exposure bake (PEB) in some instances in order to allow for conversion of the exposed regions 115 through an entire thickness of the photoresist layer 110.

Referring now to FIG. 1C, a cross-sectional illustration of the substrate 101 after the photoresist layer 110 is developed is shown. The photoresist layer 110 may be developed with a wet or dry etching process. Particularly, the unexposed regions of the photoresist layer 110 may be removed, leaving behind the exposed regions 115. The exposed regions 115 have a pattern that will subsequently be transferred into the underlying substrate 101.

Referring now to FIG. 1D, a cross-sectional illustration of the substrate 101 after an SIS process is shown. The SIS process may result in the formation of a treated region 117 in the exposed regions 115. As shown, the treated region 117 may form a shell around the exposed regions 115. Though, in some instances the exposed region may be fully converted into the treated region 117. The SIS process may include flowing precursors into the chamber, and the precursors penetrate into pores of the exposed regions 115. As illustrated, both the top surface and sidewall surfaces may be converted into treated regions 117. The top surface 103 of the underlayer 102 may also be exposed and damaged by the SIS process.

Referring now to FIG. 1E, a cross-sectional illustration of the substrate 101 after an etching process is shown. The etching process may result in features 105 that pass through the underlayer 102 and into the substrate 101. The features 105 may be trenches, holes, lines, or the like. After the etching process, the underlayer 102 and the exposed regions 115 of the photoresist layer 110 may be removed.

The process described above with respect to FIGS. 1A-1E is not without issue. One issue is that the SIS treatment is performed after the developing process. This may result in some damage to the exposed underlayer 102. The damage to the underlayer 102 may negatively impact pattern transfer into the underlying substrate 101. Additionally, the process described above may be implemented by transferring the substrate into a plurality of different tools (e.g., a resist deposition tool, an exposure tool, a developer tool, an SIS tool, an etching tool, and the like). As such, there is significant downtime between processing operations, and the substrate 101 is subject to potential damage or particle contamination.

Accordingly, embodiments disclosed herein include an SIS process that is done before the photoresist developing process. This allows for the underlayer to be protected during the SIS process. Further, the processing may be implemented, at least in part, in a cluster tool. The cluster tool includes several different processing chambers that are coupled together through a transfer chamber. As such, the substrate does not need to leave a vacuum environment between different processing operations.

In an embodiment, the photoresist patterning process described herein may be executed with either a CAR system or a metal-oxo system. Further, the photoresist material may be reactive to either EUV radiation or DUV radiation. The SIS process may also include a metal-based process or a non-metal based process.

Since the SIS process is performed before developing the photoresist, the SIS process may need to be selective between the exposed regions and the unexposed regions. For example, a change in the functional group of the photoresist may be used as the switch to selectively implement the SIS process. In one instance the functional group may change from an ester to a hydroxide upon EUV or DUV exposure.

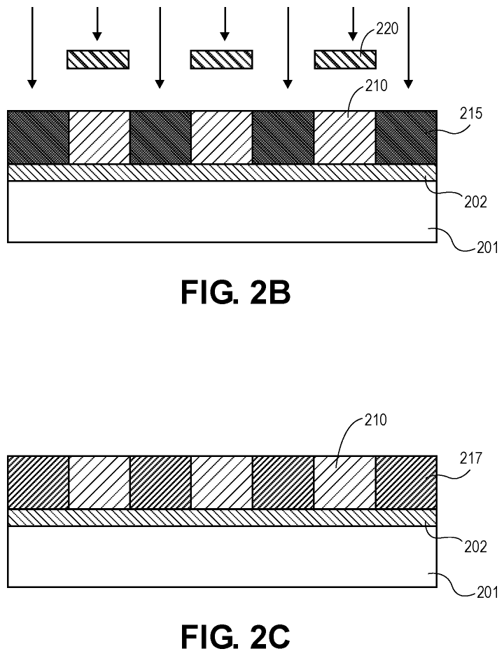

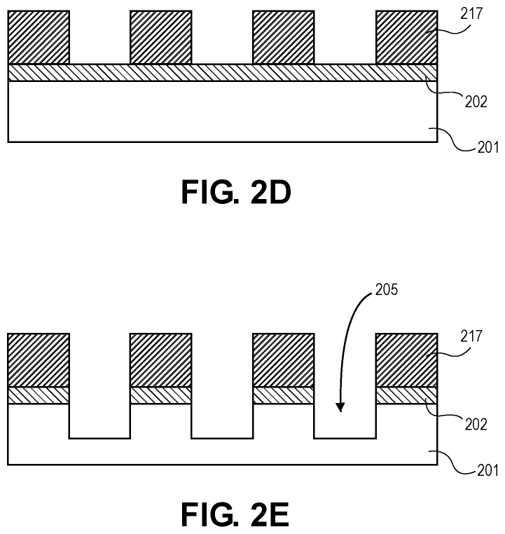

Referring now to FIGS. 2A-2E, a series of cross-sectional illustrations depicting a process for patterning a substrate 201 with a photolithography process is shown, in accordance with an embodiment. In an embodiment, the photolithography process may be an EUV or DUV process that exposes the photoresist layer, an SIS treatment of the photoresist layer, and a development of the photoresist layer.

Referring now to FIG. 2A, a cross-sectional illustration of a substrate 201 is shown, in accordance with an embodiment. The substrate 201 may be a semiconductor substrate, such as silicon. The substrate 201 may be other materials as well, such as an oxide, a nitride, a metal, or any other material useful in semiconductor fabrication operations. In an embodiment, the substrate 201 may have a form factor that is standard for semiconductor processing, such as a wafer (e.g., a 200 mm wafer, a 300 mm wafer, a 450 mm wafer, etc.).

In some embodiments, the substrate 201 may be covered by an underlayer 202. The underlayer 202 may be one or more of an ARC, a hardmask layer, or any other layer for enhancing patterning. A photoresist layer 210 may be provided over the underlayer 202. The photoresist layer 210 may be an CAR or a metal-oxo photoresist system. The photoresist layer 210 may be tuned for absorbing and reacting with EUV radiation. Though, DUV radiation may also be used in some embodiments.

Referring now to FIG. 2B, a cross-sectional illustration of the substrate 201 during a lithography exposure process is shown. The lithography exposure process may include the use of EUV or DUV radiation (indicated by the arrows) that passes through a mask 220, reticle, or the like. The openings in the mask 220 result in exposed regions 215 being formed in the photoresist layer 210. The exposed regions 215 may have an etch selectivity to the unexposed regions of the photoresist layer 210. The exposure process may be followed by a PEB in some embodiments in order to allow for conversion of the exposed regions 215 through an entire thickness of the photoresist layer 210.

Referring now to FIG. 2C, a cross-sectional illustration of the substrate 201 after an SIS treatment is shown, in accordance with an embodiment. In an embodiment, the SIS treatment results in the conversion of the exposed regions 215 into treated regions 217. The treated regions 217 may include a reinforcing structure such as a metal-oxide (e.g., alumina), or a non-metal reinforcement. Since the SIS treatment is performed before developing the photoresist 210, the SIS treatment only has access to the top surface of the exposed regions 215. As such, the SIS treatment may be performed so that the treated regions 217 diffuse through an entire thickness of the exposed regions 215. Though, in some embodiments, a partial diffusion through the thickness of the exposed regions is possible. In such partial diffusion embodiments, a dry develop process may be necessary since the entirety of the sidewalls of the exposed regions 215 may not be converted into treated regions 217.

In an embodiment, the SIS treatment may utilize a switch in the functional group of the exposed regions 215 in order to selectively treat the photoresist layer 210. For example, the unexposed regions 210 may have an ester functional group and the exposed regions 215 may have a hydroxide functional group. The SIS treatment may preferentially react with the hydroxide functional group over the ester functional group.

In an embodiment, the SIS treatment may include any type of SIS treatment. In one embodiment, the SIS treatment is a non-metal treatment. In such an embodiment, the SIS treatment may include a repeated sequence of operations. The sequence may first include exposing the photoresist layer 210 to a precursor comprising silicon or boron. The sequence may then continue with infiltrating the photoresist layer 210 with the precursor via pores contained in the photoresist layer 210. In an embodiment, the sequence further comprises purging a process region to remove gaseous remnants containing the precursor, and exposing the photoresist layer to an oxidizing agent. In an embodiment, the oxidizing agent infiltrates the photoresist layer 210 through the pores contained in the photoresist layer 210 to produce an oxide coating disposed on inner surfaces of the photoresist layer. In an embodiment, the oxide coating comprises silicon oxide or boron oxide. The process may continue with purging the process region to remove gaseous remnants containing the oxidizing agent. The sequence may be repeated any number of times in order to provide the desired level of conversion of the exposed regions into treated regions.

In another embodiment, a metal-based SIS treatment may be used. The metal-based SIS treatment may include a repeated sequence of pressurizing a methyl-containing material and an oxidizing gas into a processing environment proximate to the photoresist layer 210. While a methyl-containing material may be used as one example, embodiments are not limited to such material classes. For example, the metal precursor may also comprise diethylzinc (DEZ), which forms ZnO. The metal containing precursor (e.g., Al or Zn) infiltrates the photoresist layer 210, and a purging removes the excess precursor. Thereafter, an oxidizing gas (e.g., H₂O) is used to convert the metal precursor within the photoresist layer 210 into a metal oxide. In an embodiment, the metal oxide may comprise alumina or any other suitable metal oxide material (e.g., ZnO). Embodiments may also include using a nitrogen containing gas to form a nitride. For example, TiCl₄ can be used as the metal precursor, and NH₃ can be flown as the nitriding gas in order to form TiN. Non-metal precursors may also follow a similar SIS process. For example, SiCl₄ can be provided as a precursor and nitrided with an NH₃ gas. Such sequences may be repeated any number of times in order to provide the desired level of conversion of the exposed regions into treated regions.

Referring now to FIG. 2D, a cross-sectional illustration of the substrate 201 after a developing process is shown, in accordance with an embodiment. In an embodiment, the photoresist layer 210 may be developed by removing the unexposed regions, leaving behind the treated regions 217. The developing process may be a dry developing process or a wet developing process.

Referring now to FIG. 2E, a cross-sectional illustration of the substrate 201 after an etching process is shown, in accordance with an embodiment. In an embodiment, the etching process may be a wet or dry etching process. The etching process may result in the formation of features 205 into the substrate 201. The features 205 may be trenches, holes, lines, or the like. After the etching process, the underlayer 202 and the residual portions of the photoresist layer 210 (e.g., the treated regions 217) may be removed.

In an embodiment, the processing shown in FIGS. 2A-2E may be executed in fewer processing tools than what is described in FIGS. 1A-1E. For example, the SIS process, the develop process, and the etching process may be implemented in a single cluster tool. An example of a suitable cluster tool will be described in greater detail below. As such, there are fewer opportunities for damage or particulate contamination when using processes such as those described herein. Further, metrology tools and the like may also be included in the cluster tool in order to provide after develop inspection (ADI) and/or after etch inspection (AEI).

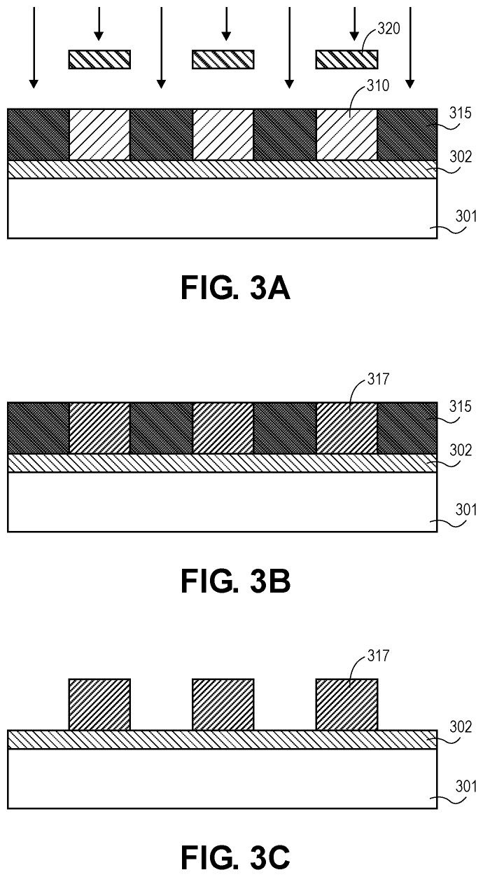

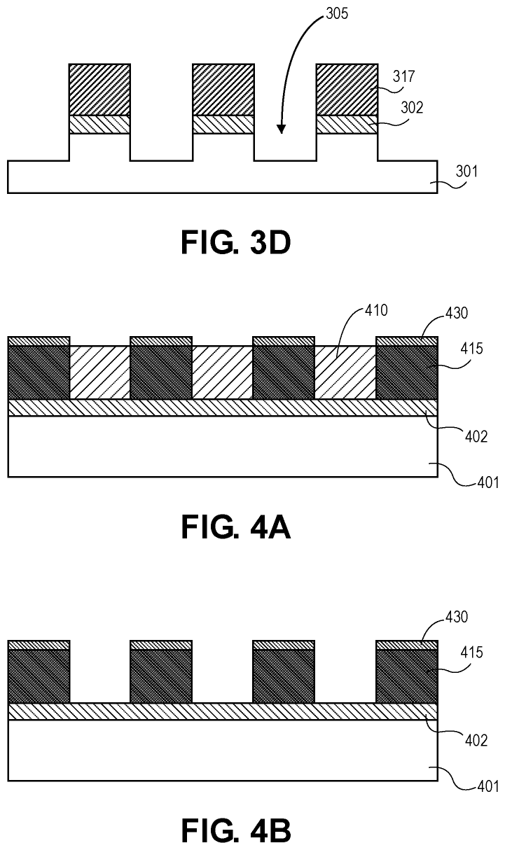

Referring now to FIGS. 3A-3D, a series of cross-sectional illustrations depicting a process for etching a substrate is shown, in accordance with an additional embodiment. The embodiment shown in FIGS. 3A-3D is similar to that shown in FIGS. 2A-2E, except with the opposite tone of photoresist developing. That is, the unexposed regions are treated with an SIS process and the exposed regions are removed before etching the substrate.

Referring now to FIG. 3A, a cross-sectional illustration of a substrate 301 during lithography exposure is shown, in accordance with an embodiment. In an embodiment, the substrate 301 may be a semiconductor, an oxide, a nitride, a metal, or any other material suitable for semiconductor manufacturing. In an embodiment, an underlayer 302 may be provided over the substrate 301, and a photoresist layer 310 may be provided over the underlayer 302. The photoresist layer 310 may be a CAR or a metal-oxo resist system. In an embodiment, a mask 320 or reticle may be used to selectively expose portions of the photoresist layer 310 to form exposed regions 315.

Referring now to FIG. 3B, a cross-sectional illustration of the substrate 301 after an SIS process is shown, in accordance with an embodiment. In an embodiment, the SIS process may be selective to the unexposed regions of the photoresist layer 310. The SIS process may be a metal-based process or a non-metal process. The SIS process may be similar to the SIS processes described in greater detail above. The SIS process may result in the formation of treated regions 317 between the exposed regions 315.

Referring now to FIG. 3C, a cross-sectional illustration of the substrate 301 after a developing process is shown, in accordance with an embodiment. In an embodiment, the developing process may result in the removal of the exposed regions 315. For example, the developing process may be implemented as a dry develop process or a wet develop process. In cases where the treated regions 317 only pass partially through a thickness of the photoresist layer 310, a dry develop process may be necessary since dry develop processes are more anisotropic in nature than wet develop processes.

Referring now to FIG. 3D, a cross-sectional illustration of the substrate 301 after an etching process is shown, in accordance with an embodiment. In an embodiment, the etching process may result in the formation of features 305 into the substrate 301. The features 305 may include trenches, holes, lines, or the like. The etching process may be a dry etching process in some embodiments.

Similar to the embodiment described above with respect to FIGS. 2A-2E, the processing in FIGS. 3A-3D may be implemented in an exposure tool and a cluster tool. More particularly, the treatment process, the develop process, and the etching process may all be implemented in a single cluster tool, with or without any associated metrology.

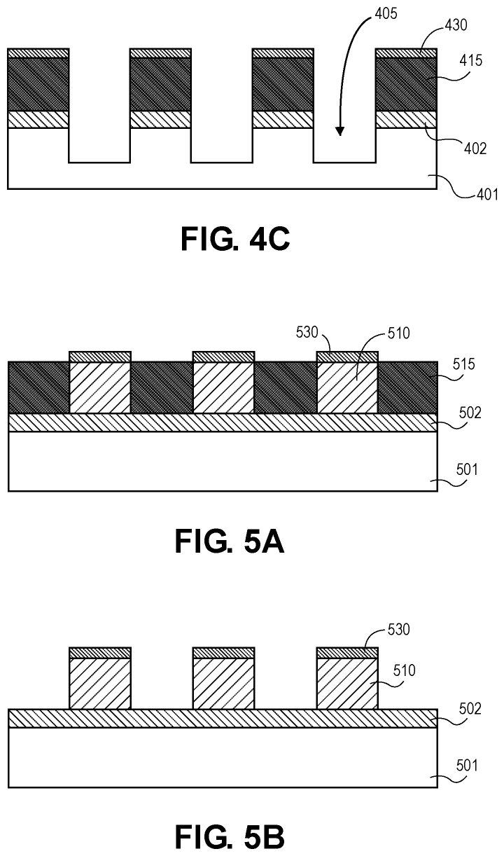

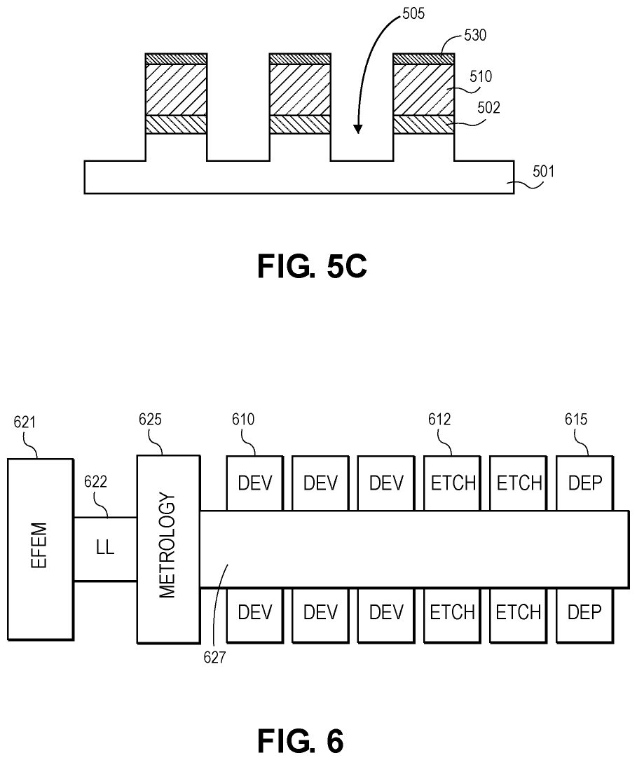

In FIGS. 2A-3D, the processing described an SIS treatment of the photoresist layers. However, embodiments are not limited to such process flows. For example, a capping layer may be provided over the exposed or unexposed regions of the photoresist in order to enhance etch selectivity with the underlying substrate. Embodiments shown in FIGS. 4A-5C provide examples of such embodiments.

Referring now to FIG. 4A, a cross-sectional illustration of a substrate 401 is shown, in accordance with an embodiment. In an embodiment, the substrate 401 may be similar to any of the substrates described in greater detail above. In an embodiment, an underlayer 402 and a photoresist layer 410 may be provided over the substrate 401. The photoresist layer 410 may be a CAR or a metal-oxo resist.

In an embodiment, the photoresist layer 410 may be exposed to include exposed regions 415 and unexposed regions 410. The exposure process may be similar to any of the exposure processes described in greater detail above. In an embodiment, a capping layer 430 may be formed over the exposed regions 415. The capping layer 430 may be a hardmask material, such as an oxide, a nitride, or the like. The capping layer 430 may be selectively formed over the exposed regions 415 using any suitable deposition process, such as atomic layer deposition (ALD), chemical vapor deposition (CVD), or self-assembled monolayer (SAM) deposition. The deposition process may also take place in a cluster tool.

Referring now to FIG. 4B, a cross-sectional illustration of the substrate 401 after a developing process is shown, in accordance with an embodiment. In an embodiment, the developing process may remove the unexposed regions of the photoresist layer 410. The developing process may be a dry developing process in some embodiments. Though, a wet process may also be used in some instances.

Referring now to FIG. 4C, a cross-sectional illustration of the substrate 401 after an etching process is shown, in accordance with an embodiment. In an embodiment, the etching process results in the formation of features 405 (e.g., trenches, holes, lines, etc.) in the substrate 401. After etching, the underlayer 402 and the remaining portion of the photoresist layer 410 may be removed.

In an embodiment, the processing described in FIGS. 4A-4C may all be implemented in a single cluster tool. For example, the cluster tool may include a deposition chamber to deposit the capping layer 430, a dry develop chamber to develop the photoresist layer 410, and an etching chamber to etch the substrate 401.

Referring now to FIGS. 5A-5C, a series of cross-sectional illustrations depicting a process for etching a substrate 501 is shown, in accordance with an additional embodiment. The embodiment shown in FIGS. 5A-5C is substantially similar to the embodiment described in FIGS. 4A-4C, with the exception of the photoresist being the opposite tone. That is the unexposed regions persist after the developing process.

Referring now to FIG. 5A, a cross-sectional illustration of a substrate 501 is shown, in accordance with an embodiment. In an embodiment, the substrate 501 may be similar to any of the substrates described in greater detail above. In an embodiment, an underlayer 502 and a photoresist layer 510 may be provided over the substrate 501. The photoresist layer 510 may be a CAR or a metal-oxo resist.

In an embodiment, the photoresist layer 510 may be exposed to include exposed regions 515 and unexposed regions 510. The exposure process may be similar to any of the exposure processes described in greater detail above. In an embodiment, a capping layer 530 may be formed over the unexposed regions 510. The capping layer 530 may be a hardmask material, such as an oxide, a nitride, or the like. The capping layer 530 may be selectively formed over the unexposed regions 510 using any suitable deposition process, such as ALD, CVD, or SAM deposition. The deposition process may also take place in a cluster tool.

Referring now to FIG. 5B, a cross-sectional illustration of the substrate 501 after a developing process is shown, in accordance with an embodiment. In an embodiment, the developing process may remove the exposed regions 515 of the photoresist layer 510. The developing process may be a dry developing process in some embodiments. Though, a wet process may also be used in some instances.

Referring now to FIG. 5C, a cross-sectional illustration of the substrate 501 after an etching process is shown, in accordance with an embodiment. In an embodiment, the etching process results in the formation of features 505 (e.g., trenches, holes, lines, etc.) in the substrate 501. After etching, the underlayer 502 and the remaining portion of the photoresist layer 510 may be removed.

In an embodiment, the processing described in FIGS. 5A-5C may all be implemented in a single cluster tool. For example, the cluster tool may include a deposition chamber to deposit the capping layer 530, a dry develop chamber to develop the photoresist layer 510, and an etching chamber to etch the substrate 501.

Referring now to FIG. 6, a plan view illustration of a cluster tool 600 is shown, in accordance with an embodiment. In an embodiment, the cluster tool 600 may comprise an equipment front end module (EFEM) 621. The EFEM 621 may receive front opening unified pods (FOUPs), cassettes, or the like as an entry point for substrates into the cluster tool 600. The substrates that are processed in the cluster tool 600 may include wafers (e.g., silicon wafers, or other semiconductor wafers) with any standard form factor, (e.g., 200 mm, 300 mm, 450 mm, etc.). In an embodiment, the EFEM 621 may be coupled to the rest of the cluster tool 600 through a load lock 622. The load lock 622 may separate an atmospheric condition in the EFEM from a vacuum condition in the rest of the cluster tool 600. Though, in some embodiments, the EFEM may also be held at a su-atmospheric pressure (e.g., a higher pressure than on the other side of the load lock 622).

In an embodiment, a metrology tool 625 may be provided after the load lock 622. The metrology tool 625 may be a scatterometry tool or any other metrology tool useful for ADI or AEI applications. In an embodiment, the metrology tool 625 may be communicatively coupled with a transfer chamber 627. The transfer chamber 627 may include robotic arms, tracks, or any suitable architecture for transporting the substrates between the metrology tool 625 and the remainder of the cluster tool 600.

In an embodiment, one or more develop chambers 610 and one or more etch chambers 612 may be coupled to the transfer chamber 627. For example, six develop chambers 610 and four etch chambers 612 are provided in the cluster tool 600. One or more deposition chambers 615 may also be provided in the cluster tool 600. The chambers 610, 612, and 615 may be provided on two sides of the transfer chamber 627 in order to optimize space savings. In an embodiment, the develop chambers 610 may be dry develop chambers. A plasma source may be used in conjunction with the develop chambers 610 in order to develop the resist layers without any wet chemistries. Additionally, the etch chambers 612 may be dry etching chambers 612 that use plasma to etch the substrate through the resist layer. The deposition chambers 615 may be dry deposition chambers (e.g., ALD, CVD, etc.) that are used to deposit photoresist layers and/or capping layers.

In an embodiment, the substrate may enter the EFEM, pass through the load lock 622 and the metrology tool 625 and be delivered to one of the develop chambers 610. After developing, the substrate may be delivered to the metrology tool 625 for ADI. After ADI, the substrate may be delivered to one of the etch chambers 612 through the transfer chamber 627. There, the substrate may be etched through the developed resist layer. The substrate may then be transferred back to the metrology tool 625 for AEI. Accordingly, the operations of resist development, deposition of capping layers, ADI, substrate etching, and AEI may occur within a single cluster tool 600 without needing to leave a vacuum environment.

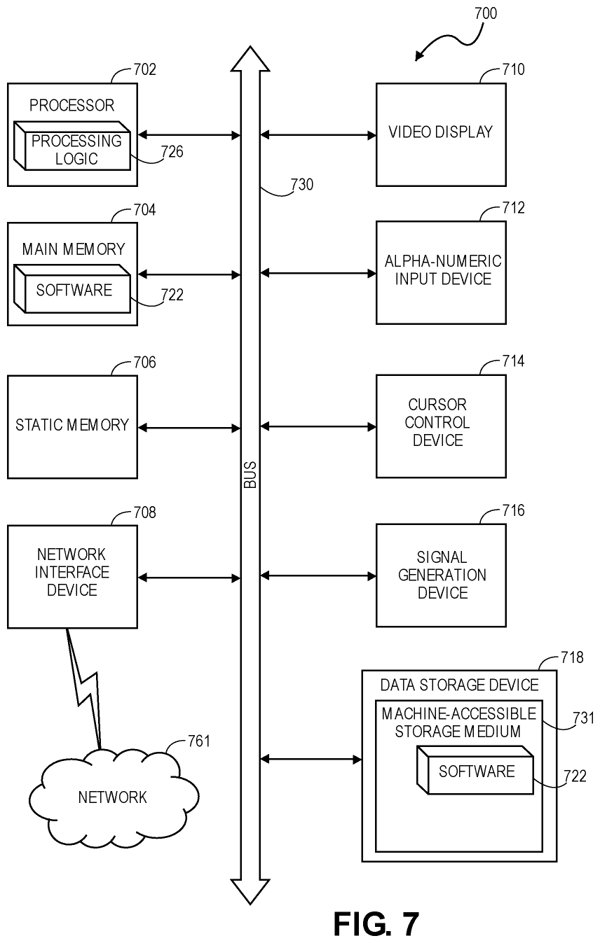

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), MRAM, etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of exposing a photoresist, implementing an SIS process on the photoresist, developing the photoresist, and etching the underlying substrate. The process may be implemented at least in part with a cluster tool. The cluster tool may include a metrology tool, a develop chamber, a deposition chamber, and an etch chamber. In an embodiment, the methods disclosed herein allow for improved etching performance compared to conventional methods.

Thus, methods for processing substrates using SIS processes where the substrate resides in a cluster tool with a metrology tool, a dry develop chamber, a deposition chamber, and an etch chamber are described.

What is claimed is:

1. A method of patterning a substrate, comprising:
disposing a photoresist layer over a substrate;
exposing the photoresist layer to form an exposed region and an unexposed region in the photoresist layer;
treating either the exposed region or the unexposed region with a sequential infiltration synthesis (SIS) process to form a treated region; and
developing the photoresist layer to remove either portions of the treated region or portions of the photoresist layer other than the treated region.

2. The method of claim 1, wherein the SIS process is a metal SIS process.

3. The method of claim 1, wherein the SIS process is a non-metal SIS process.

4. The method of claim 1, wherein the treated region passes through an entire thickness of the photoresist layer.

5. The method of claim 1, wherein the treated region passes partially through a thickness of the photoresist layer.

6. The method of claim 4, wherein developing the photoresist layer is done with a dry process.

7. The method of claim 1, further comprising:
etching the substrate using the treated region as a mask.

8. The method of claim 1, wherein the SIS process and the developing is done in a single cluster tool.

9. The method of claim 1, wherein the photoresist layer is a chemically amplified resist (CAR) or a metal-oxo resist.

10. A cluster tool to pattern a substrate with a photoresist layer, comprising:
a first chamber;
a second chamber coupled to the first chamber;
a third chamber coupled to the first chamber and the second chamber;
wherein the substrate with the photoresist layer is exposed with extreme ultraviolet (EUV) radiation to form an exposed region and an unexposed region;
wherein the first chamber is configured to selectively treat either the exposed region or the unexposed region with a sequential infiltration synthesis (SIS) process to form a treated region;
wherein the second chamber is configured to develop the photoresist layer so that the treated region remains; and
wherein the third chamber is configured to etch the substrate using the treated region as a mask.

11. The cluster tool of claim 10, further comprising a fourth chamber, wherein a metrology is performed on the substrate in the fourth chamber after develop and/or after etch.

12. The cluster tool of claim 10, wherein developing the photoresist layer in the second chamber is a thermal dry develop process.

13. The cluster tool of claim 10, wherein the photoresist layer comprises a chemically amplified resist (CAR) or a metal-oxo resist.

14. A cluster tool to pattern a substrate with a photoresist layer, comprising:
a first chamber;
a second chamber coupled to the first chamber;
a third chamber coupled to the first chamber and the second chamber;
wherein the photoresist layer is exposed to extreme ultraviolet (EUV) radiation to form an exposed region and an unexposed region;
wherein the first chamber is configured to selectively deposit a capping layer over either the exposed region of the unexposed region;
wherein the second chamber is configured to develop the photoresist layer so that the capping layer and the underlying one of the exposed region or the unexposed region remain; and
wherein the third chamber is configured to etch the substrate using the capping layer and the underlying one of the exposed region or the unexposed region as a mask.

15. The cluster tool of claim 14, further comprising:
a fourth chamber coupled to the first chamber, the second chamber, and the third chamber, wherein the fourth chamber is a metrology chamber configured to perform metrology on the substrate after developing and/or after etching.

16. The cluster tool of claim 14, wherein developing the photoresist layer in the second chamber is a thermal dry develop process.

17. The cluster tool of claim 14, wherein the photoresist layer comprises a chemically amplified resist (CAR) or a metal-oxo resist.

18. The cluster tool of claim 14, wherein depositing the capping layer is done with an atomic layer deposition, a chemical vapor deposition, or a self-assembled monolayer process.

19. The cluster tool of claim 14, wherein the capping layer is selectively deposited as a result of a functional group change resulting from the EUV exposure.

20. The cluster tool of claim 14, wherein the first chamber, the second chamber, and the third chamber a coupled together by a transfer chamber, and wherein the first chamber, the second chamber and the third chamber are on the same side of a load lock in the cluster tool.
